(19) United States
(12) Patent Application Publication
(10) Pub. No.: US 2026/0237589 A1
(43) Pub. Date: Aug. 13, 2026

(54) LINE EDGE SMOOTHING WITH JITTERED TWIST

(71) Applicant: Axcelis Technologies, Inc., Beverly, MA (US)

(72) Inventor: James DeLuca, Beverly, MA (US)

(21) Appl. No.: 19/531,733

(22) Filed: Feb. 6, 2026

Related U.S. Application Data
(60) Provisional application No. 63/756,309, filed on Feb. 10, 2025.

(51) Int. Cl. H01J 37/08; H01J 37/20; H01J 37/304

(52) U.S. Cl. CPC H01J 37/08; H01J 37/20; H01J 37/304; H01J 2237/24528; H01J 2237/24535

(57) ABSTRACT

During a line edge smoothing process, a controlled oscillation is provided between a mask feature orientation and the ion beam. By continuously rotating the wafer within a narrow range of twist angles during the line edge smoothing process, the system compensates for alignment errors and deviations from linearity and parallelism in the mask features. The oscillations improve the uniformity and repeatability of the line edge smoothing process across the wafer and from wafer to wafer. By reducing sensitivity of the process to alignment errors, the invention eliminates the need for extensive setup, calibration, and fine-tuning. The manufacturing process is streamlined, enabling faster production cycles while increasing precision and repeatability, ultimately enhancing device performance and design margins.

### REFERENCE TO RELATED APPLICATIONS

This application claims the benefit of U.S. Provisional Application Serial No. 63/756,309 filed February 10, 2025, the contents of all of which are herein incorporated by reference in their entirety.

### BACKGROUND

Mask line edge smoothing is a process used in the semiconductor industry to refine the edges of a mask for improved precision and uniformity in pattern transfer. Ion beam systems may be employed for this purpose. During the process, a wafer with a mask having substantially straight, substantially parallel linear features is rotated to align these features with an ion beam. The ion beam is then scanned across the wafer surface while the wafer is held at a grazing angle relative to the ion beam. This configuration allows the ions to sputter away edge asperities, enhancing the uniformity and repeatability of manufacturing processes that rely on the mask.

### BRIEF DESCRIPTION OF THE DRAWINGS

FIG. 1 illustrates an ion beam system that can embody some aspects of the present disclosure.

FIGS. 2A-2B illustrate a substrate support system that can be a part of the ion beam system of FIG. 1.

FIG. 2C illustrates an ion beam’s angle of incidence on a wafer held by the substrate support system in FIG. 2B.

FIG. 3 illustrates an aligner that can be used in some aspects of the present disclosure.

FIGS. 4A-C illustrate some deviations from parallelism in substantially straight and substantially parallel linear features on a substrate.

FIGS. 5A-5C illustrate how the angular difference between a projection of an ion beam onto a wafer surface and a feature orientation is made to oscillate between positive and negative values in accordance with the present disclosure.

FIG. 6 provides a flow chart for a semiconductor device manufacturing process in accordance with some embodiments.

FIG. 7 illustrates an example distribution of substantially straight and substantially parallel linear features on a wafer.

### DETAILED DESCRIPTION

The present disclosure provides many different embodiments, or examples, for implementing different features of this disclosure. Specific components and arrangements are provided to clarify and exemplify the disclosure. These specific examples should not be interpreted as limiting the scope of what is described and claimed.

The present disclosure addresses challenges of mask line edge smoothing in semiconductor manufacturing, particularly those challenges that are exacerbated when the ion beam is inclined at a steep angle relative to the wafer. Increasing the angle of incidence enhances sputter yield and selectivity for removing mask material projecting into the channels between straight and parallel mask lines, but also amplifies the effects of deviations from ideal conditions. These deviations arise from several sources: local or cross-wafer irregularities in mask feature orientation and parallelism, variations in ion beam directionality due to beam divergence or imperfections in beam forming and steering, and inaccuracies in mechanical alignment during patterning of the mask feature and during the smoothing process itself.

The present disclosure solves these problems by introducing a controlled oscillation into the twist angle between the wafer and the ion beam. By continuously rotating the wafer within a narrow range of twist angles during the line edge smoothing process, the system compensates for deviations from parallelism and linearity, and also compensates for alignment errors. The oscillations average over the imperfections, improving uniformity and repeatability across the wafer and from wafer to wafer. By reducing sensitivity of the process to alignment errors, the invention eliminates the need for extensive setup, calibration, and fine-tuning. The manufacturing process is streamlined, enabling faster production cycles while increasing precision and repeatability, ultimately enhancing device performance and design margins.

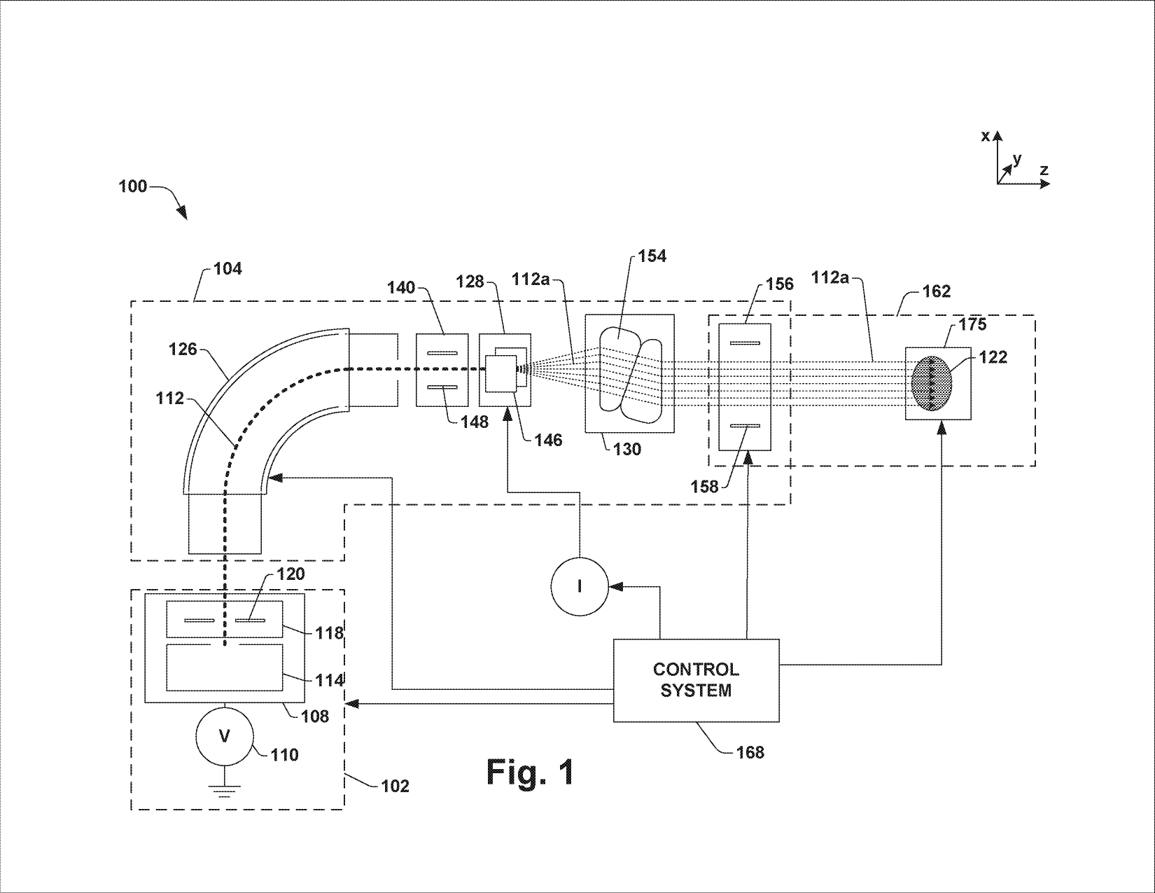

FIG. 1 illustrates an ion beam system 100 that, if outfitted with a suitable substrate holder and controller, can provide an embodiment of the present invention. In the specific exemplary embodiment illustrated in FIG. 1, the ion beam system 100 is an ion implantation system (and is described as such hereinafter), but it will be appreciated that the inventive concepts disclosed herein may also apply to other ion beam systems including, but not limited to, focused ion beam (FIB) systems, ion beam sputter/deposition systems, and ion beam etching/milling systems. The ion beam system 100 includes a terminal 102, a beam steering system 104, and an end station 162. The terminal 102 includes an ion source 108 that produces ions that are extracted and formed into an ion beam 112. The beam steering system 104 filters, shapes and steers the ion beam 112. The end station 162 includes a substrate support system 175 for holding wafers 122 that are treated with the ion beam 112.

The ion source 108 may include an arc chamber 114 and an ion extraction assembly 118. The arc chamber 114 is supplied with a gas that includes the species to be ionized and extracted. Within the arc chamber 114, electrons are generated from an electron source. The electron source may be a filament or cathode that is heated with a current from a high voltage power supply 110 to induce thermionic emission of electrons. The electrons may be induced to arc and ionize some of the gas in the arc chamber 114 generating a plasma. A magnetic field may be provided to maintain the plasma in a swirl. The ions may be controllably extracted from the plasma and accelerated to a beam steering system energy by the ion extraction assembly 118. The ion extraction assembly 118 may include electrodes 120 that accelerate the extracted ions.

The beam steering system 104 may include a mass analyzer 126, a beam shaping system 140, a scanning system 128, a parallelizer 130, and optionally a deceleration stage 156. The mass analyzer 126 filters the ions based on charge-to-mass ratio so that after the mass analyzer 126 the ion beam 112 is a purified ion beam that includes only select ions. In the illustrated example, the mass analyzer 126 includes a bend through which the ions are deflected by a magnetic field. Ions having the wrong charge-to-mass ratio will be over-deflected or under-deflected so that only the ions having the desired charge-to-mass ratio continue down the beam steering system 104 from the mass analyzer 126.

The beam shaping system 140 includes one or more electrical or magnetic lenses 148 that compress and steer the ion beam 112. In some embodiments, the beam shaping system 140 includes a first quadrupole magnet that squeezes the ion beam 112 in the x-direction (an x-quad) and a second quadrupole magnet that squeezes the ion beam 112 in the y-direction (a y-quad). The y-direction is into the page of FIG. 1. The scanning system 128 steers the ion beam 112 successively through the beam paths 112a to sweep the ion beam 112 in the x-direction (fast scan direction). The scanning system 128 may include plates 146. The plates 146 may steer the ion beam 112 either electrically or magnetically. In some embodiments, the scanning system 128 sweeps the beam path 112a cyclically at a rate that is above 1 Hz, e.g., 100 Hz or more.

The scanned ion beam 112 may be passed through a parallelizer 130. In the illustrated example, the parallelizer 130 includes two dipole magnets 154. The two dipole magnets 154 may be substantially trapezoidal and oriented to mirror one another and bend the beam paths 112a into s-shapes. The parallelizer 130 has the effect of making all the beam paths 112a substantially parallel.

The deceleration stage 156 can be disposed within the end station 162 downstream from the parallelizer 130. The deceleration stage 156 can include one or more electrodes 158 that slow the ion beam 112 and focus the ion beam 112 into a converging stream. In some embodiments, the beam steering system 104 upstream from the end station 162 is maintained at a first potential and the deceleration stage 156 is maintained at a second potential. Placing the deceleration stage 156 within the end station 162 facilitates maintaining this potential difference. The deceleration stage 156 can slow and focus the ion beam 112. In some embodiments, the deceleration stage 156 includes an Einzel lens.

The end station 162 comprises a substrate support system 175 within a vacuum chamber. The substrate support system 175 is configured to hold, orient, and translate a wafer 122 or other substrate while holding the wafer 122 in the path of the ion beam 112. A wafer is a thin, flat, circular substrate which is often a slice of semiconductor material. Common diameters are 150 mm, 200 mm, and 300 mm. The substrate support system 175 can be configured to translate the wafer 122 so as to cause the ion beam 112 to sweep across the wafer 122 in a y-direction sweep (slow scan direction). The y-direction sweeps are at a slower rate than the x-direction sweeps, e.g., about 1 Hz or less.

Ion implantations systems with alternative scanning mechanism are also compatible with the invention. In some embodiments, the beam steering system 104 spreads the ion beam into a ribbon that includes all of the beam paths 112a so that an x-direction sweep may be unnecessary. In some other embodiments, the beam steering system 104 steers the ion beam 112 to provide both the y-direction sweep in addition to the x-direction sweep so that the wafer 122 does not need to be translated to effectuate the scan.

A control system 168 is operatively coupled to the ion source 108, the beam steering system 104, and the substrate support system 175 or their respective subsystems to provide communication and control. The control system 168 is an electronic control system and can comprise one or more computers, each including a central processing unit and a memory system programmed with suitable instructions for implementing relevant communication and control functions.

The control system 168 determines the rate of ion production in the ion source 108, the energy of the ions entering the beam steering system 104, the energy of the ions exiting the beam steering system 104, the fast scan rate, the slow scan rate, etc. The control system 168 includes predefined control settings through which an end user can adjust these and other parameters. The collection of predefined control settings and other selections available to an end-user of the ion beam system 100 constitute a recipe through which an operator may direct the ion beam system 100 to conduct a specific and reproducible line edge smoothing or other operation.

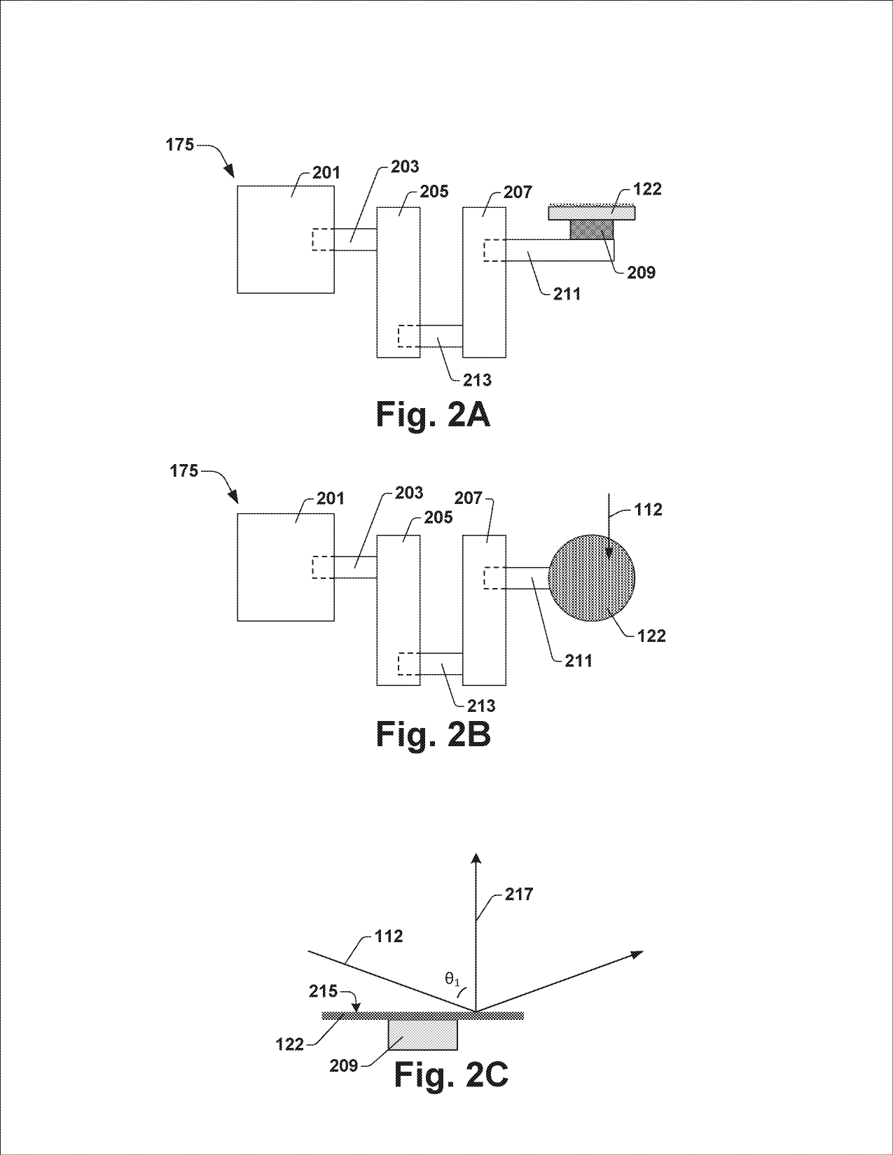

FIG. 2A and 2B illustrate an example of the substrate support system 175 in accordance with some embodiments. As shown in FIG. 2A-2B, the substrate support system 175 includes a base 201, a first arm 205, a second arm 207, and a rotatable substrate holder 209. The rotatable substrate holder 209 may include a mechanical chuck, an electrostatic chuck, a vacuum chuck, or some other type of chuck suitable for holding the wafer 122 during treatment with the ion beam 112. The rotatable substrate holder 209 is pivotally connected to the second arm 207 through a joint 211. The second arm 207 is pivotally connected to the first arm 205 through a joint 213. The first arm 205 is pivotally connected to a base 201 through a joint 203. These joints provide multiple degrees of freedom that allow the substrate support system 175 to position the wafer 122 at a selectable angle of incidence with respect to the ion beam 112 (see FIG. 1) and to keep the wafer 122 in a fixed plane while moving the wafer through the ion beam 112 to effectuate scanning in the y-direction.

As shown in FIG. 2A, the wafer 122 may be facing in a first direction when it is received by the substrate support system 175. As shown in FIG. 2B together with FIG. 2C, the substrate support system 175 can rotate the wafer 122 about the joint 211 so that the ion beam 112 has an angle of incidence θ₁ on the wafer surface 215 (angle with respect to a surface normal 217). For the line edge smoothing process, the angle of incidence θ₁ is steep, e.g., at least 30 degrees. In some embodiments, the angle of incidence θ₁ is in the range from about 40 degrees to about 85 degrees, which is a more practical range for a line edge smoothing process. In some embodiments, the angle of incidence θ₁ is in the range from about 60 degrees to about 80 degrees, which is typical for a line edge smoothing process. In some embodiments, the angle of incidence θ₁ is greater than about 80 degrees. These steeper angles of incidence are made feasible by the present invention.

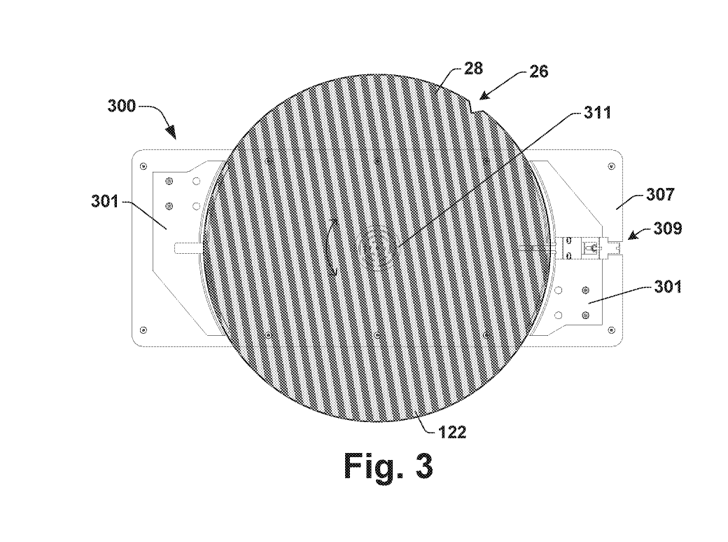

FIG. 3 illustrates the wafer 122 on an aligner 300. The aligner 300 can be integral with the ion beam system 100, or can be in a wafer transport system that provides wafers 122 to the substrate support system 175 with a known orientation. As shown in FIG. 3, the wafer 122 has patterned features 28, which are substantially straight and substantially parallel, and an alignment feature 26. The alignment feature 26 may be a notch (a small V-shaped cut) as in the illustration, a flat (a small straight cut), or the like. An orientation of the patterned features 28, which is a feature orientation, may be predetermined in relation to the alignment feature 26. The feature orientation may be determined at the time the patterned features 28 are formed or in a subsequent inspection process. The aligner 300 rotates the wafer 122 and sets its angular orientation relative to the alignment feature 26 so that the feature orientation is known when the wafer 122 is held on the rotatable substrate holder 209 (see FIGS. 2A and 2C).

The aligner 300 includes a base 307, workpiece supports 301, a chuck 311, and an alignment mark detection device 309. The workpiece supports 301 may have arcuate recesses configured to support a perimeter of the wafer 122. The chuck 311 is rotatably mounted to the base 307 so that it can grip and rotate the wafer 122. The alignment mark detection device 309 may be an optical sensor or some other type of sensing device capable of detecting the alignment feature 26.

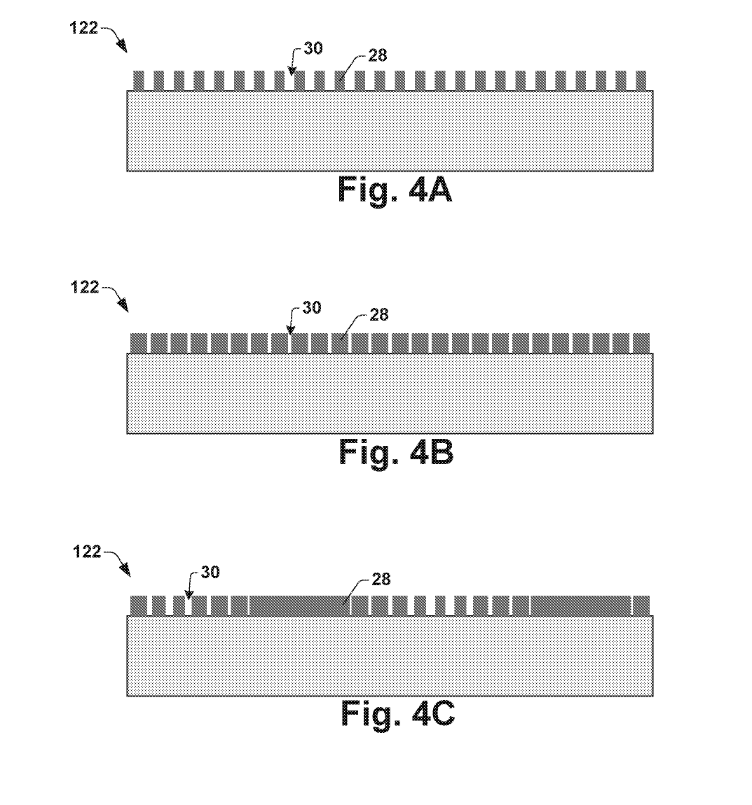

FIGS. 4A-C show cut-away side views of the wafer 122 and are provided to illustrate the challenge of projecting an ion beam 112 along the feature direction. FIG. 4A illustrates an ideal case in which the patterned features 28 are perfectly straight and perfectly parallel and there is a view down the channels 30 between the patterned features 28. FIG. 4B shows a non-ideal case. In FIG. 4B, the patterned features 28 have the same widths as in FIG. 4A, but the channels 30 appear narrower due to waviness or some other deviation from parallelism that may be uniformly distributed. FIG. 4C shows another non-ideal case, one in which the deviations from parallelism are non-uniformly distributed across the wafer 122. In all these cases, the patterned features 28 are substantially straight and substantially parallel. For example, all the patterned features 28 may be within about 2 degrees of a single orientation through their entire lengths. In other words, the deviations from parallelism among patterned features 28 may all be within a 2 degree range. As the term is used herein, “deviations from parallelism” encompasses deviations from parallelism between one part and another of a single patterned feature 28 and deviations from parallelism between different patterned features 28.

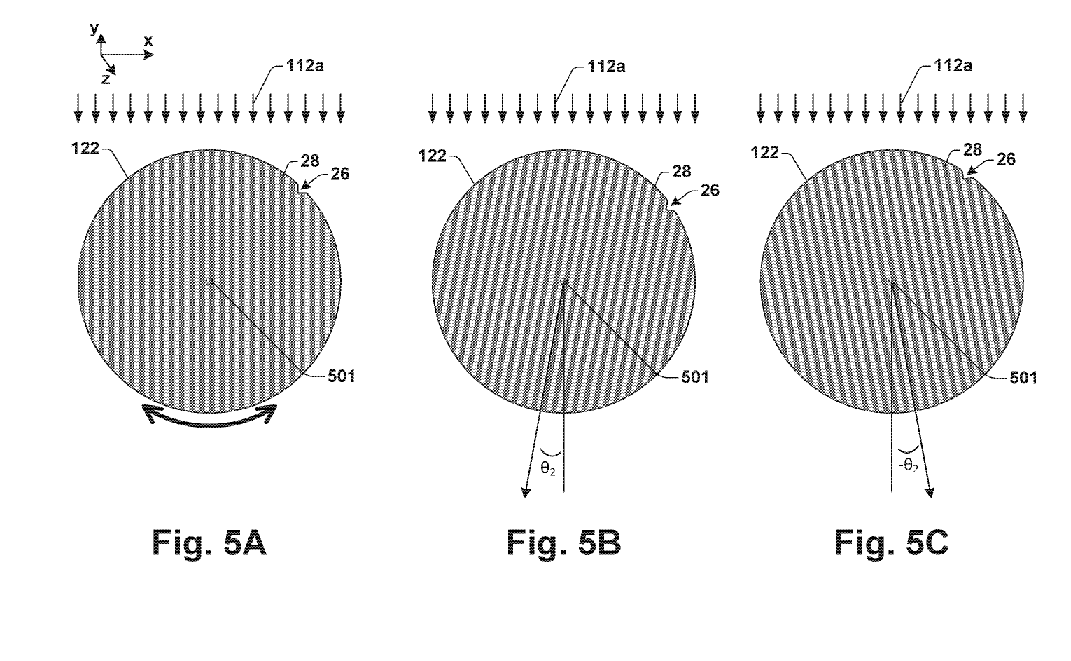

FIGS. 5A-C illustrate a line edge smoothing process. As shown in FIG. 5A, the wafer 122 is made to undergo an oscillatory angular rotation about its central axis 501 as it is scanned by the ion beam 112. The ion beam 112 may move successively through the beam paths 112a to effectuate a scan in the x-direction. The wafer 122 may be translated by the substrate support system 175 (see FIG. 2B) to effectuate a scan in the y-direction. The ion beam 112 has an angle of incidence θ₁ (see FIG. 2C) which may remain constant as it is scanned across the surface 215.

As shown in FIGS. 5A-5C, the angular rotations are oscillatory about the position shown in FIG. 5A in which a projection of the ion beam 112 onto the wafer 122 is aligned with the feature orientation. The angular rotations cause an angular difference θ₂ between a projection of the ion beam onto the wafer surface and the feature orientation to oscillate between a positive value as shown in FIG. 5B and a negative value as shown in FIG. 5C. In some embodiments, the oscillations are within a range of 10 degrees or less. In some embodiments, the oscillations are within a range of 4 degrees or less. In some embodiments, the oscillations are within a range of 2 degrees or less. An oscillation of ± 2 degrees (a 4 degrees range) is generally more than enough to accommodate deviations from parallelism and uncertainty in alignment of the wafer 122. If the range of the oscillations is too small, the process may be ineffective to compensate for the deviations from parallelism or the alignment error. If the range of the oscillations is too great, the efficiency of the line edge smoothing process may be diminished.

The oscillations have a higher rate than a rate at which the ion beam 112 scans across the wafer 122. If the ion beam 112 scans the wafer 122 in both fast scan and slow scan directions, the oscillations are at a faster rate than the fast scan sweeps across the wafer 122. In some embodiments, there are from about 2 to about 10 oscillations per fast scan sweep. In some embodiments, the oscillations are at a rate of about 20 hertz or more. In some embodiments, the oscillations are at a rate of about 40 hertz or more. In some embodiments, the oscillations are at a rate of about 80 hertz or more. If the oscillations are too slow, the process may be ineffective to average over the deviations from parallelism.

In some embodiments, the ions in the ion beam 112 are N+, Ar+, Xe+ or the like. Heavier inert gas ions are most suitable for line edge smoothing. In some embodiments, the line edge smoothing process uses low energy ions. For example, the ions may be provided with energies at or below 1 kV. In some embodiments, the line edge smoothing process uses a high ion dose. A high ion dose may be, for example, about 1 x 10¹⁴ atoms per cm². In some embodiments, the dose is about 1 x 10¹⁵ atoms per cm² or more. These and other parameters may be determined as part of a recipe for a line edge smoothing process.

The ion beam system 100 may be designed or adapted to perform the line edge smoothing process with oscillations in accordance with the present disclosure. In some embodiments, designing or adapting the ion beam system 100 to perform the wafer oscillations includes programming the control system 168 to include predefined control settings related to the oscillations, which then become part of the recipe. These parameters may relate to whether the oscillations occur, a range for the oscillations, and/or a frequency for the oscillations.

In some embodiments, the rotatable substrate holder 209 has mechanical and/or electrical adaptations for producing rapid oscillations in the rotational orientation of the wafer 122 or other substrate. Examples of mechanical adaptations may include, without limitation, a piezoelectric actuator, non-commutated DC linear actuator, or a mechanical spring or damper. Examples of electrical adaptations may include, without limitation, a circuit or electronic device that generates a periodic signal such as a sinusoidal or square wave signal having a frequency corresponding to the oscillation rate. These adaptations may be additional to the systems that enable the substrate support system 175 to orient, rotate, and translate the wafer 122 for ion implantation and other such processes.

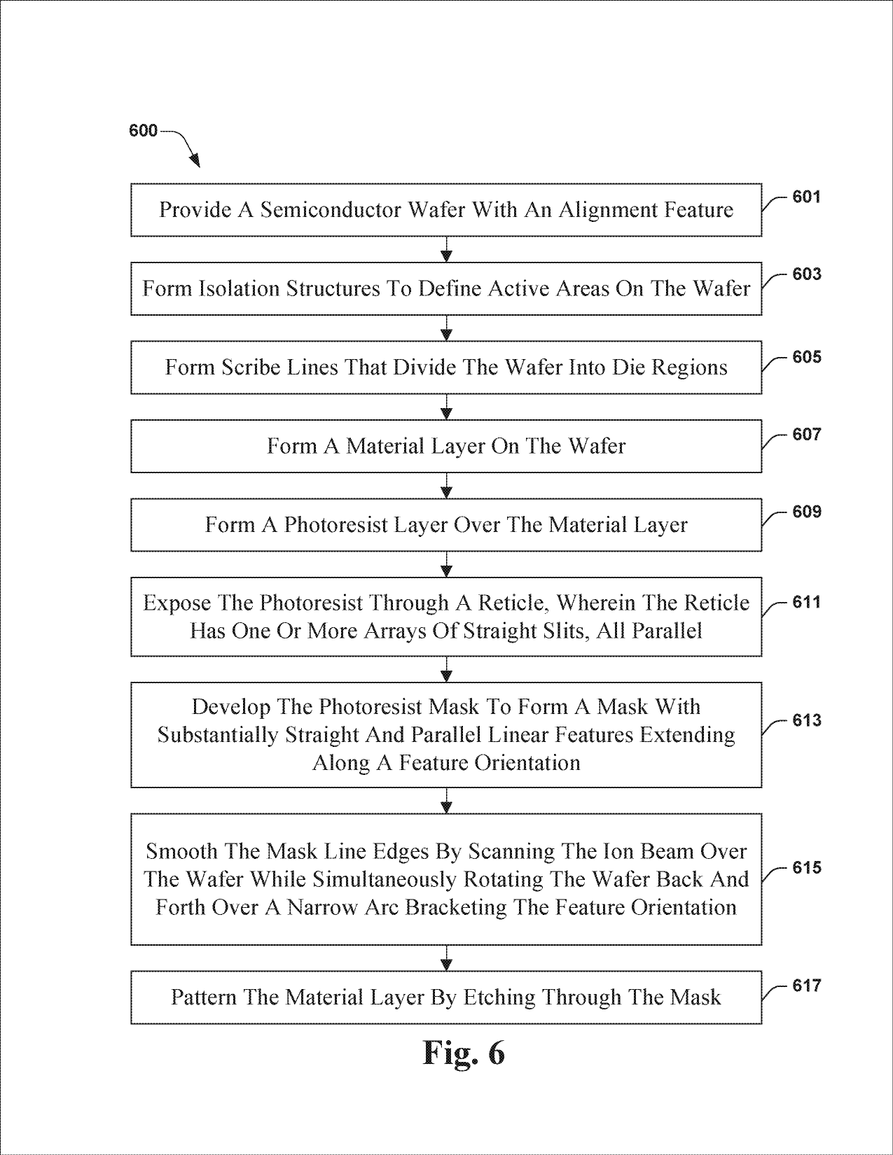

FIG. 6 illustrates a flowchart for a semiconductor device manufacturing process 600 that incorporates a line edge smoothing process in accordance with the present disclosure. While the process 600 is depicted as a series of sequential acts or events, it should be understood that the process is not limited to the specific sequence or arrangement shown. In some embodiments, the described acts may be performed in a different order than illustrated and/or executed concurrently. Additionally, certain acts or events may be subdivided into multiple components, which may occur independently or simultaneously with other acts. Moreover, some of the depicted acts or events may be optional and omitted, while other acts or events not explicitly illustrated may be included while remaining within the scope of the present disclosure.

The process 600 begins with act 601, providing a semiconductor wafer with an alignment feature on its edge. Semiconductor wafers with alignment features, such as notches or flats, serve as exemplary embodiments for this process. However, it should be understood that the process is not limited to semiconductor wafers with alignment features. The process may be applied to other types of substrates, including those with varying shapes, as well as instances where orientation is determined in the absence of an alignment feature.

Act 603 is forming isolation structures that define active areas on the wafer. Act 605 is creating scribe lines that divide the wafer into die regions. Act 607 is forming a material layer on the wafer. The material layer may be any type of material that is to be patterned using a mask. The material layer may be, for example, polysilicon, a metal, a dielectric, or a stack of various materials. Act 609 is forming a photoresist layer over the material layer. The photoresist may be applied by any suitable process, for example, spin coating. The photoresist may be a positive photoresist or a negative photoresist.

Act 611 is exposing the photoresist to a light source through a reticle containing straight parallel linear slits arranged in one or more arrays. The exposure process may be carried out using a step-and-repeat or step-and-scan approach, enabling the sequential treatment of the wafer’s entire surface by exposing a few die areas—such as one, four, or sixteen die areas—at a time. The reticle may provide one array for each die area or multiple arrays, with each array corresponding to a distinct active area. Each array has straight parallel linear slits and all of the slits in all of the arrays have the same orientation. The exposure pattern is applied consistently across all the die areas on the wafer.

After the exposure process is complete, the photoresist is developed in act 613 to provide substantially straight and parallel features all having the same feature orientation within manufacturing tolerances. Even if the slits in the reticle are perfectly parallel, imperfections in the foregoing pattern transfer process will create some deviations from parallelism. The term “substantially parallel” should therefore be understood as parallel but for deviations from parallelism ordinarily encountered in commercial applications of the foregoing process steps.

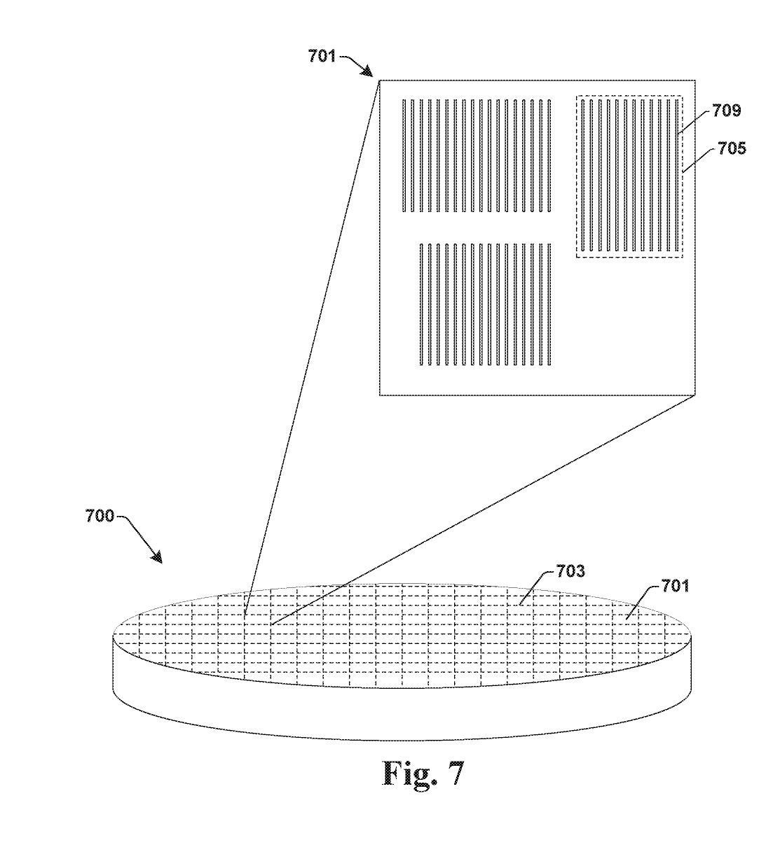

FIG. 7 illustrates a wafer 700 with a mask pattern produced by the foregoing process steps. The wafer 700 includes die areas 701 separated by scribe lines 703. The expanded view of one of the die areas 701 shows three arrays 705, each comprising a plurality of straight linear features 709 corresponding to slits in the mask. It should be appreciated that this type of feature distribution is typical for the patterned features 28 shown in FIGS. 4A-4C and 5A-5C and that those figures show simplified patterns for ease of illustration and to clarify the description.

Due to the nature of the pattern transfer process, the patterned features 28 may have rough edges. Returning to FIG. 6, act 615 is a mask line edge smoothing process according to the present disclosure, i.e., a process in which an ion beam is scanned over the wafer while simultaneously rotating the wafer back and forth over a narrow arc bracketing the feature orientation. After the line edge smoothing process, act 617 transfers the mask pattern to the underlying material layer by etching through the mask openings. The line edge smoothing process could alternatively be applied to a hard mask or other patterned layer, and that patterning could be by a process other than photolithography.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. In addition, while a particular feature may have been disclosed with respect to only one of several embodiments, such feature may be combined with one or more other features of the other embodiments as may be desired or advantageous for a given application.

What is claimed is:

1. An ion beam system, comprising:
an ion source configured to generate an ion beam;
a beam steering system configured to direct the ion beam;
a substrate support system configured to hold and rotate a wafer;
a control system configured to:
operate the ion source to generate the ion beam;
operate the beam steering system, the substrate support system, or both, to scan the ion beam across the wafer; and
during scanning of the ion beam across the wafer, rotate the wafer to modulate a relative angular orientation between the ion beam and a feature orientation of the wafer by varying the angular orientation back and forth between:
a first deviation, corresponding to a positive angular offset between a projection of the ion beam onto the wafer and the feature orientation; and
a second deviation, corresponding to a negative angular offset between the projection of the ion beam onto the wafer and the feature orientation.

2. The ion beam system of claim 1, wherein the control system is further configured to allow an operator to select the feature orientation and to selectively enable or disable the rotation of the wafer during scanning of the ion beam across the wafer, wherein the selections are made through predefined control settings provided by the control system.

3. The ion beam system of claim 1, wherein the control system is further configured to allow an operator to select a frequency at which the relative angular orientation between the ion beam and the feature orientation is varied back and forth between the first deviation and the second deviation, wherein the selection is made through predefined control settings provided by the control system.

4. The ion beam system of claim 1, wherein the control system is further configured to allow an operator to select the positive and negative angular offsets or a difference between them, wherein the selection is made through predefined control settings provided by the control system.

5. The ion beam system of claim 1, wherein the substrate support system is configured to position the wafer at an angle of incidence relative to the ion beam of at least 30 degrees and less than 90 degrees, and the control system is configured to operate the beam steering system, the substrate support system, or both, to scan the ion beam across the wafer while maintaining the wafer at the angle of incidence relative to the ion beam.

6. An ion beam system, comprising:
an ion source configured to generate an ion beam;
a beam steering system configured to direct the ion beam along a beam direction;
a substrate support system including a rotatable substrate holder; and
a control system programmed to:
generate the ion beam using the ion source;
scan the ion beam across a substrate held inclined relative to the ion beam by the rotatable substrate holder; and
while the scan is in progress, oscillate the substrate between first and second orientations.

7. The ion beam system of claim 6, wherein the ion beam system is configured to detect an orientation feature on the substrate and determine the first and second orientations relative to the orientation feature.

8. The ion beam system of claim 6, wherein the control system allows the oscillations to be selectively enabled or disabled through a user interface.

9. The ion beam system of claim 6, wherein:
the ion beam system is an ion implantation system;
the ion beam is a spot beam;
the beam steering system is configured to scan the ion beam along a first scanning direction; and
the substrate support system is configured to scan the ion beam along a second scanning direction, which is perpendicular to the first scanning direction.

10. A method of line edge smoothing, comprising:
generating an ion beam using an ion beam system including an ion source configured to generate the ion beam, and a beam steering system configured to direct the ion beam along a beam direction;
directing the ion beam toward a surface of a wafer having an edge and a feature orientation defined relative to an alignment feature on the edge, using the beam steering system, wherein the wafer surface is inclined relative to the ion beam;
scanning the ion beam over the wafer surface by varying the beam direction, translating the wafer, or both; and
while scanning the ion beam across the wafer surface, rotating the wafer so that an angular difference between a projection of the ion beam onto the wafer surface and the feature orientation oscillates between positive and negative values.

11. The method of claim 10, further comprising:
scanning the ion beam over the wafer surface by using the beam steering system to scan the ion beam repeatedly across the wafer surface in a fast scan direction and translating the wafer in a slow scan direction; and
rotating the wafer to vary the angular difference between the positive and negative values at least twice each time the ion beam scans across the wafer surface in the fast scan direction.

12. The method of claim 11, wherein the wafer surface is maintained in a fixed plane while translating the wafer in the slow scan direction.

13. The method of claim 10, further comprising:
disposing a mask having linear features on the wafer surface, wherein the linear features have a variation in parallelism; and
rotating the wafer to vary the angular difference by an amount greater than the variation in parallelism.

14. The method of claim 10, wherein the angular difference oscillates between the positive and negative values at a rate of at least 20 hertz.

15. The method of claim 10, wherein the wafer surface is inclined to form an angle of 30 degrees or less with the beam direction.

16. The method of claim 10, wherein the angular difference is limited to a range of 10 degrees or less while rotating the wafer.

17. The method of claim 10, further comprising:
disposing a mask having linear features on the wafer surface, wherein the linear features have a distribution of orientations; and
rotating the wafer to vary the angular difference by an amount greater than a range of the distribution of orientations and less than 10 degrees.

18. The method of claim 10, wherein the ion beam system is configured to perform the oscillations at a frequency sufficient to compensate for variations in directionality within a set of substantially parallel straight linear features on the wafer surface.

19. The method of claim 10, wherein:
the ion beam has a beam angle variation while it is scanned across the wafer surface; and
the oscillations have a range greater than the beam angle variation.

20. The method of claim 10, wherein:
the wafer is held and rotated by a substrate support system while scanning the ion beam over the wafer surface, wherein the substrate support system has an electronic controller;
the substrate support has an angular range of variation, which is a mean deviation between an angular position specified by the electronic controller and an actual angular position of the wafer held by the substrate support; and
the oscillations have a range greater than the angular range of variation.
